(19) United States
(12) Patent Application Publication
(10) Pub. No.: US 2003/0122088 A1
(43) Pub. Date: Jul. 3, 2003

(54) Scan methods and apparatus for ion implantation

(75) Inventors: Alan P. Sheng, Gloucester, MA (US); Marvin R. LaFontaine, Kingston, NH (US)

Correspondence Address: Mark Superko, Varian Semiconductor, Equipment Associates, Inc., 35 Dory Lane, Gloucester, MA, 01930-2297, US

(73) Assignee: Varian Semiconductor Equipment Associates, Inc., Gloucester, MA (US)

(21) Appl. No.: 10/294,225

(22) Filed: Nov. 14, 2002

Related U.S. Application Data
(60) Provisional application No. 60/333,052, filed on Nov. 14, 2001.

(51) Int. Cl. H01J 37/08; G21K 5/10

(52) U.S. Cl. 250/492.21; 250/492.3

(57) ABSTRACT

An ion implanter is provided having an ion beam generator for generating an ion beam, a platen for holding a workpiece, such as a semiconductor wafer, and a tilt mechanism for tilting the platen and the wafer with respect to the ion beam. A scan controller mechanically moves the wafer and the platen relative to the ion beam so that the motion of the wafer and the platen is tangential, i.e. parallel, to the wafer surface. As a result, the ion beam intersects the wafer surface at a fixed position along the beamline as the wafer is scanned. The size and shape of the ion beam are thereby constant over all areas of the wafer surface during the implant for increasing implant uniformity.

### RELATED APPLICATION

This application claims priority under 35 U.S.C. §119(e) to U.S. provisional patent application Serial No. 60/333,052, filed Nov. 14, 2001, entitled “Scan Methods and Apparatus for Ion Implantation”, the disclosure of which is herby incorporated by reference.

### FIELD OF THE INVENTION

This invention relates to systems and methods for ion implantation of semiconductor wafers and other workpieces and, more particularly, to methods and apparatus for scanning semiconductor wafers relative to an ion beam to achieve dose uniformity.

### BACKGROUND OF THE INVENTION

Ion implantation is a standard technique for introducing conductivity-altering impurities into semiconductor wafers. A desired impurity material is ionized in an ion source, the ions are accelerated to form an ion beam of prescribed energy and the ion beam is directed at the surface of the wafer. The energetic ions in the beam penetrate into the bulk of the semiconductor material and are embedded into the crystalline lattice of the semiconductor material to form a region of desired conductivity.

Ion implantation systems usually include an ion source for converting a gas or a solid material into a well-defined ion beam. The ion beam is mass analyzed to eliminate undesired ion species, is accelerated to a desired energy and is directed onto a target plane. The beam may be distributed over the target area by beam scanning, by target movement or by a combination of beam scanning and target movement. An ion implanter which utilizes a combination of beam scanning and target movement is disclosed in U.S. Pat. No. 4,922,106, issued May 1, 1990 to Berrian et al.

In a typical ion implanter, the wafer is held in an end station by a mechanical system which is capable of precisely moving, or scanning, the wafer through the ion beam to perform an implant of the wafer. The wafer may be tilted with respect to the ion beam at a tilt angle that is determined by the recipe for the devices being manufactured. The tilt angle can take on a variety of values.

A variety of scanning methods have been incorporated into known ion implanters. All scanning methods have the goal of distributing the ions in the ion beam as uniformly as possible over the wafer surface. Since the ion beam is typically smaller than the wafer, the ion beam is scanned relative to the wafer to achieve a two-dimensional scan pattern that completely covers the wafer surface.

In one known ion implanter, the two-dimensional pattern is achieved by lateral translation of a spinning disk, as shown in FIGS. 1A and 1B. As shown, wafers 10 are mounted around the periphery of a disk 12, and an ion beam 14 is directed at the disk 12. A spinning component of disk motion produces scanning in one lateral direction, while a translational component of disk motion provides scanning in an orthogonal direction.

In another known ion implanter, one wafer at a time is implanted, as opposed to the batch implant of several wafers in the spinning disk approach described above. In the single wafer ion implanter, scanning may be accomplished by a combination of mechanical wafer scanning and electrostatic beam scanning, as shown in FIG. 2. A wafer 40 is held on a platen 42, and an ion beam 44 is directed at wafer 40. Wafer 40 and platen 42 are mechanically scanned in a vertical direction relative to ion beam 44, as indicated by arrow 46, and the ion beam 44 is electrostatically scanned in an orthogonal direction.

In yet another approach, a ribbon beam having a width at least as great as the diameter of the wafer is utilized. The wafer is mechanically scanned perpendicular to the width of the ribbon ion beam to distribute the beam over the wafer surface.

A disadvantage of known ion implanters is that the uniformity of an implant may be reduced by the inherent geometrical effects of the scanning methods utilized. In most cases, the ion beam is not perfectly cylindrical in shape, nor is the ion density distribution uniform. Instead, the beam typically diverges or converges in the direction of beam transport. Thus, the size, shape and ion density profile of the ion beam vary with position along the beamline. A problem arises when the wafer is tilted at an angle relative to the incident ion beam. As the tilted wafer is translated through the ion beam, the wafer surface intercepts an ion beam of varying size, shape and ion density profile. This is a result of an implant zone on the wafer surface moving along the beamline as the wafer is scanned vertically, due to the tilt of the wafer.

As shown in FIG. 3, wafer 40 at the bottom of the vertical scan along the vertical direction as indicated by arrow 46 (position 50) is implanted in a zone Z₁, and wafer 40 at the top of the vertical scan (position 52) is implanted in a zone Z₂. As further shown in FIG. 3, zone Z₂ is displaced along beamline 48 from zone Z₁, by a distance d. In the case where ion beam 44 is converging, zone Z₂ is larger than zone Z₁. In the case where ion beam 44 is diverging (not shown), zone Z₂ is smaller than zone Z₁. The result of the varying size and shape of the ion beam at its intersection with the wafer surface is that the density of implanted ions varies across the surface. This non-uniformity of ion density significantly reduces the quality of the devices which are being fabricated. The non-uniformity is more pronounced for large wafers and/or large tilt angles.

### SUMMARY OF THE INVENTION

According to an aspect of the invention, an ion implanter comprises an ion beam generator for generating an ion beam, a platen for holding a workpiece, such as a semiconductor wafer, and a tilt mechanism for tilting the platen and the wafer with respect to the ion beam. A scan system mechanically moves the wafer and the platen relative to the ion beam so that the motion of the wafer and the platen is tangential, i.e. parallel, to the wafer surface. As a result, the ion beam intersects the wafer surface at a fixed position along the beamline as the wafer is scanned. The size and shape of the ion beam are then constant over all areas of the wafer surface during the implant. The effect is to increase implant uniformity in comparison with known scanning techniques.

More particularly, the scan system includes a first scan mechanism for scanning the wafer and the platen in a first direction perpendicular to the ion beam and a second scan mechanism for scanning the wafer and the platen in a second direction parallel to the ion beam. A controller controls the first and second scan mechanisms such that the resulting motion of the platen is parallel to the wafer surface.

In a first embodiment, the second scan mechanism moves the wafer, the platen, the tilt mechanism and the first scan mechanism in the second direction relative to a fixed element.

In a second embodiment, the first scan mechanism is fixed in position along the second direction. The second scan mechanism moves the wafer, the platen and the tilt mechanism in the second direction relative to a movable element of the first scan mechanism.

In a third embodiment, the scan system includes a scan mechanism for moving the wafer and the platen relative to the tilt mechanism in a direction parallel to the wafer surface.

### BRIEF DESCRIPTION OF THE DRAWINGS

For a better understanding of the present invention, reference is made to the accompanying drawings, which are incorporated herein by reference and in which:

FIGS. 1A and 1B are front and side schematic diagrams, respectively, of a known spinning disk used for ion implantation;

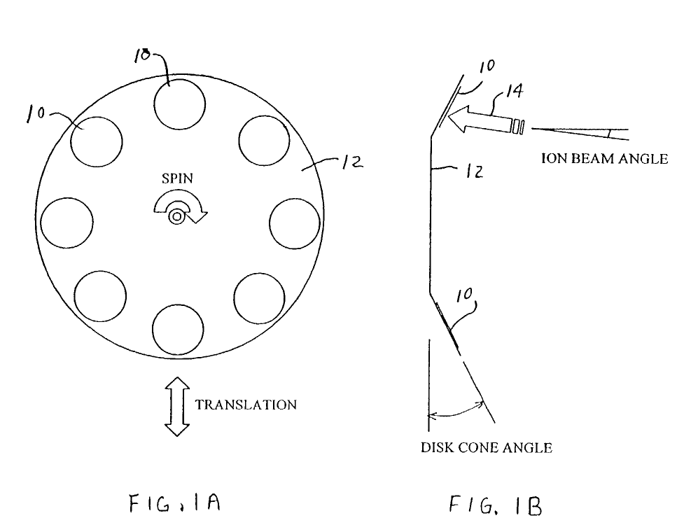

FIG. 2 is a schematic diagram that illustrates a known single wafer scan technique;

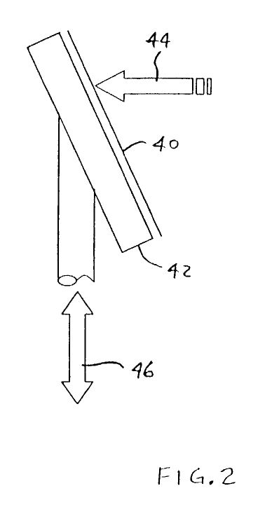

FIG. 3 is a schematic diagram that illustrates a source of non-uniformity when implanting a tilted wafer in known ion implanters;

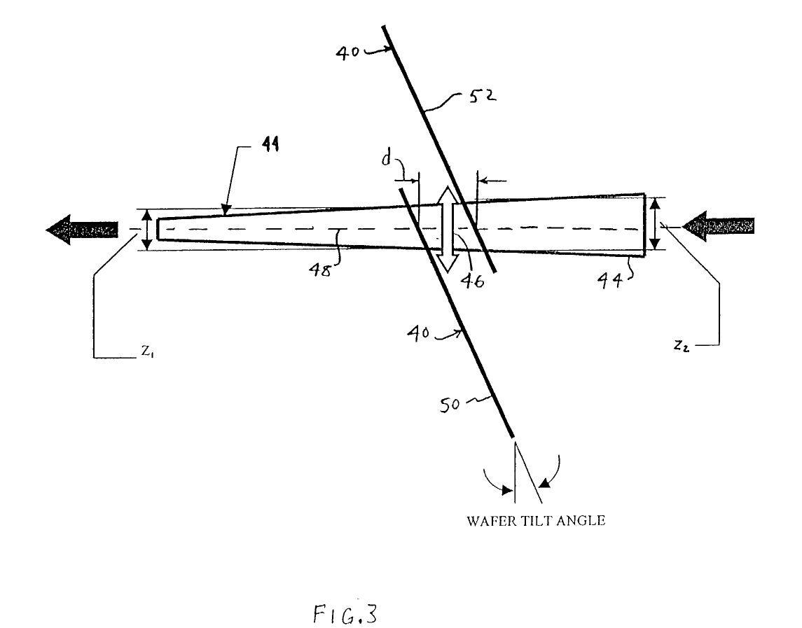

FIG. 4 is a schematic diagram that illustrates wafer scanning in accordance with a first embodiment of the invention;

FIG. 5 is a schematic diagram that illustrates wafer scanning in accordance with a second embodiment of the invention;

FIG. 6 is a schematic diagram that illustrates wafer scanning in accordance with a third embodiment of the invention; and

FIGS. 7A and 7B are block diagrams of embodiments of a scan control system.

### DETAILED DESCRIPTION

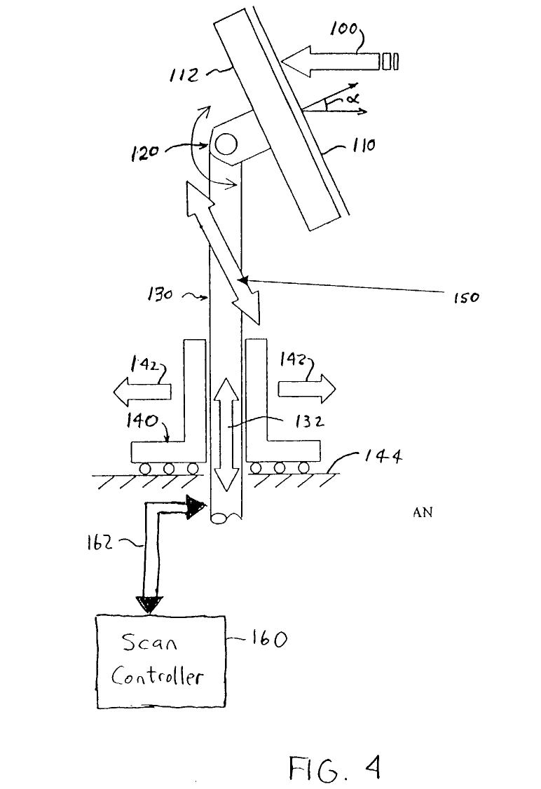

A schematic diagram of an ion implanter in accordance with a first embodiment of the invention is shown in FIG. 4. An ion beam generator (not shown) generates an ion beam 100 that may be scanned in a direction normal to the plane of FIG. 4 or may comprise a ribbon beam having a cross-section with a long dimension normal to the plane of FIG. 4. Ion beam 100 is directed at the surface of a semiconductor wafer 110 mounted on a platen 112, which may comprise an electrostatic wafer clamp. A tilt mechanism 120 permits wafer 110 and platen 112 to be tilted at a tilt angle α relative to ion beam 100 in response to control from a scan controller 160. The scan controller 160 may be implemented as a microprocessor or a dedicated controller and connected to the ion implanter by a bus 162 or other known optical and electrical connectors. The tilt angle α is typically defined as the angle between a normal to the surface of wafer 110 and the direction of ion beam 100.

The ion implanter further includes a scan system for mechanically scanning tilted wafer 110 relative to ion beam 100. The scan system includes a first scan mechanism 130 for mechanically scanning wafer 110, platen 112 and tilt mechanism 120 in a direction, indicated by arrow 132, perpendicular to ion beam 100. First scan mechanism 130 typically scans wafer 110 in a vertical direction in response to control by the scan controller 160. The scan system further includes a second scan mechanism 140 for mechanically scanning wafer 110, platen 112, tilt mechanism 120 and first scan mechanism 130 in a direction, indicated by arrows 142, parallel to ion beam 100. The second scan mechanism 140 typically scans wafer 110 in a horizontal direction. Second scan mechanism 140 moves wafer 110, platen 112, tilt mechanism 120 and first scan mechanism 130 relative to a fixed element 144, such as the frame of the ion implanter, in response to control by the scan controller 160.

The first scan mechanism 130 and the second scan mechanism 140 operate simultaneously during a implant and produce a resulting motion of wafer 110 in a direction indicated by arrow 150 in FIG. 4. In particular, the resulting motion of wafer 110 is the vector sum of the motions produced by first scan mechanism 130 and second scan mechanism 140 as follows:

\hat{x}ₚₗₐₜₑₙ=\hat{x}_{vertical}+\hat{x}_{horizontal}

where \hat{x}ₚₗₐₜₑₙ, \hat{x}_{vertical} and \hat{x}_{horizontal} represent the vector motions of the platen 112, the first scan mechanism 130 and the second scan mechanism 140, respectively. The motions of wafer 110 produced by first scan mechanism 130 and second scan mechanism 140 are coordinated, as described below, such that the resulting motion of platen 112 is parallel to the surface of wafer 110. As a result, wafer 110 intercepts ion beam 100 at a fixed position along ion beam 100 during mechanical scanning. Thus, an ion beam having a constant size and shape is implanted into wafer 110.

Tilt mechanism 120 may include a tiltable element and a motor or other suitable actuator for moving the tiltable element to a desired tilt angle in response to control by the scan controller 160. Scan mechanisms 130 and 140 may each include a movable element and a motor or other suitable actuator for scanning the movable element along a desired path.

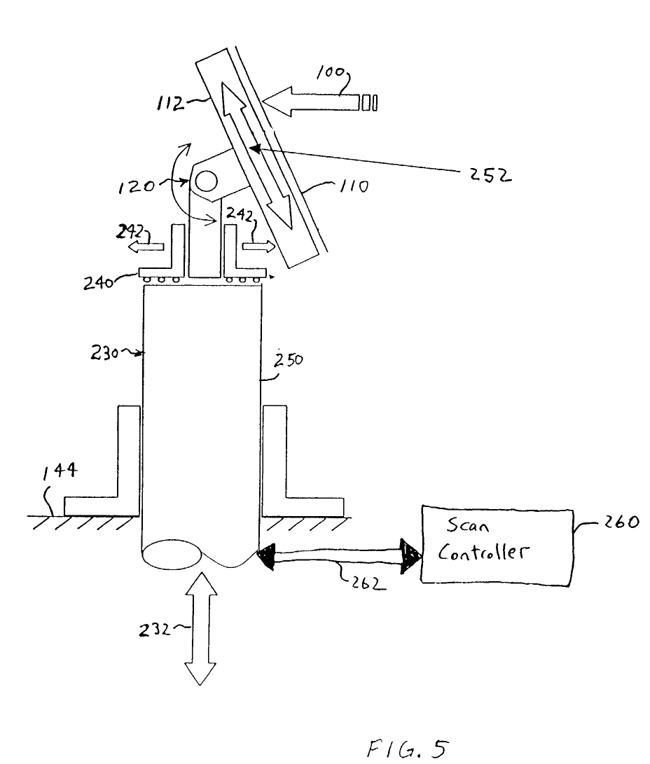

A schematic diagram of an ion implanter in accordance with a second embodiment of the invention is shown in FIG. 5. Like elements in FIGS. 4 and 5 have the same reference numerals. The ion implanter of FIG. 5 includes a scan system for mechanically scanning tilted wafer 110 relative to ion beam 100. The scan system includes a first scan mechanism 230 for mechanically scanning wafer 110, platen 112 and tilt mechanism 120 in a direction, indicated by arrow 232, perpendicular to ion beam 100. First scan mechanism 230 typically scans wafer 110 in a vertical direction. The scan system further includes a second scan mechanism 240 for mechanically scanning wafer 110, platen 112 and tilt mechanism 120 in a direction, indicated by arrows 242 parallel to ion beam 100. The second scan mechanism 240 typically scans wafer 110 in a horizontal direction.

In the embodiment of FIG. 5, second scan mechanism 240 is mounted to a vertically movable element 250 of first scan mechanism 230, such as a shaft. Thus, second scan mechanism 240 moves wafer 110, platen 112 and tilt mechanism 120 relative to the vertically movable element 250 of first scan mechanism 230. The first scan mechanism 230 and the second scan mechanism 240 operate simultaneously in response to control by a scan controller 260, which is connected to the ion implanter via a bus 262, during an implant and produce a resulting motion of platen 112 in a direction, indicated by arrow 252 in FIG. 5, parallel to the surface of wafer 110. In the embodiment of FIG. 5, the vertically movable element 250 of first scan mechanism 230 has a fixed position in the direction indicated by arrow 242.

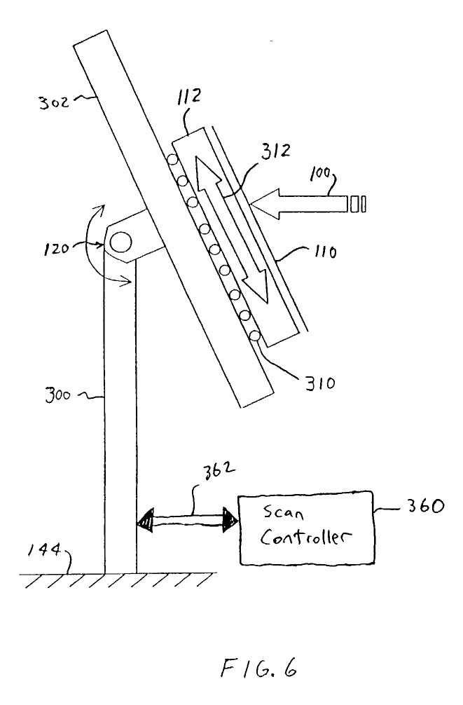

A schematic diagram of an ion implanter in accordance with a third embodiment of the invention is shown in FIG. 6. Like elements in FIGS. 4 and 6 have the same reference numerals. Tilt mechanism 120 includes a stationary element 300 mounted to fixed element 144 and a tiltable element 302 pivotally mounted to stationary element 300.

The ion implanter includes a scan system for mechanically scanning tilted wafer 110 relative to ion beam 100. The scan system includes a scan mechanism 310 for scanning wafer 110 and platen 112 relative to tiltable element 302 of tilt mechanism 120 in a direction parallel to the wafer surface, as indicated by arrow 312, in response to a scan controller 360 connected to the ion implanter via a bus 362.

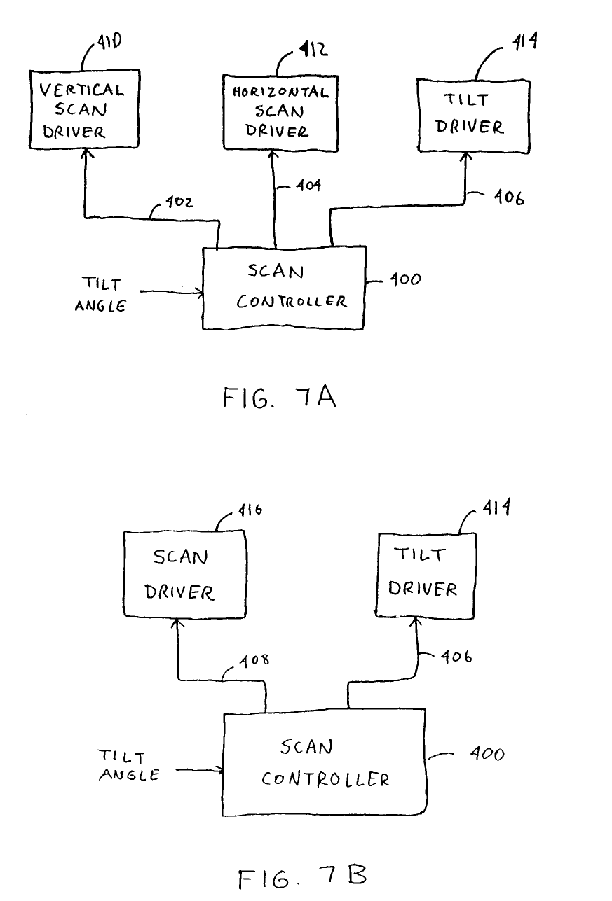

A block diagram of a control system suitable for controlling the scan systems of FIGS. 4 and 5 is shown in FIG. 7A. A scan controller 400 receives a tilt angle to be utilized for an implant process. The tilt angle may be input by a system operator or may be stored as part of an implant recipe. Scan controller 400 may be implemented as a microprocessor or a dedicated controller. Scan controller 400 is coupled to a vertical scan driver 410 via a bus 402 which operates first scan mechanism 130 in the embodiment of FIG. 4 or first scan mechanism 230 in the embodiment of FIG. 5. Scan controller 400 is further coupled to a horizontal scan driver 412 via a bus 404 which operates second scan mechanism 140 in the embodiment of FIG. 4 or second scan mechanism 240 in the embodiment of FIG. 5. The scan drivers 410 and 412 may comprise linear motors or similar linear actuators. Scan controller 400 is further coupled to a tilt driver 414 via a bus 406 which moves wafer 110 and platen 112 to the specified tilt angle.

The scan controller 400 coordinates the operation of vertical scan driver 410 and horizontal scan driver 412 to produce mechanical scanning of platen 112 in a direction parallel to the wafer surface. In particular, scan controller 400 determines from the tilt angle the required travel and speed of each scan driver to produce scanning parallel to the wafer surface.

For controlling the embodiment of FIG. 6, the vertical scan driver 410 and the horizontal scan driver 412 are replaced by a single scan driver 416 that moves wafer 110 and platen 112 relative to tiltable element 302 as shown in FIG. 7B. Since the embodiment of FIG. 6 utilizes a single scan mechanism, coordination between scan mechanisms is not required.

While there have been shown and described what are at present considered the preferred embodiments of the present invention, it will be obvious to those skilled in the art that various changes and modifications may be made therein without departing from the scope of the invention as defined by the appended claims.

1. An ion implanter comprising:
an ion source for generating an ion beam;
a platen for holding a workpiece;
a tilt mechanism for tilting said workpiece and said platen to a predetermined angle relative to said ion beam;
a scan mechanism for simultaneously scanning said workpiece and said platen in perpendicular and parallel directions to said ion beam; and
a controller for controlling said scan mechanism to move said platen parallel to a surface of said workpiece so that the size and shape of said ion beam are maintained constant over the entirety of said surface of said workpiece.

2. An ion implanter as defined in claim 1, wherein said workpiece comprises a semiconductor wafer.

3. An ion implanter as defined in claim 1, wherein said ion beam is a beam substantially having a cylindrical shape.

4. An ion implanter as defined in claim 1, wherein said ion beam is a ribbon beam.

5. An ion implanter as defined in claim 4, wherein said ribbon beam comprises a cross-section with a long dimension along said parallel scan direction.

6. An ion implanter as defined in claim 1, wherein said scan mechanism comprises a first scan mechanism for scanning said workpiece in a direction perpendicular to said ion beam and a second scan mechanism for scanning said workpiece in a direction parallel to said ion beam.

7. An ion implanter as defined in claim 6, wherein said second scan mechanism is configured to scan said workpiece, said platen, said tilt mechanism and said first scan mechanism in said direction parallel to said ion beam relative to a fixed element.

8. An ion implanter as defined in claim 6, wherein said second scan mechanism is configured to scan said workpiece, said platen and said tilt mechanism in said direction parallel to said ion beam relative to a movable element of said first scan mechanism.

9. A method for ion implanting comprising the steps of:
(a) generating an ion beam directed towards a workpiece held on a platen;
(b) tilting said workpiece and said platen to a predetermined angle relative to said ion beam;
(c) simultaneously scanning said workpiece and said platen in perpendicular and parallel directions to said ion beam; and
(d) controlling said step (c) to move said platen parallel to a surface of said workpiece so that the size and shape of said ion beam are maintained constant over the entirety of said surface of said workpiece.

10. A method as defined in claim 9, wherein said work piece comprises a semiconductor wafer.

11. A method as defined in claim 9, wherein said ion beam is a beam substantially having a cylindrical shape.

12. A method as defined in claim 9, wherein said ion beam is a ribbon beam.

13. A method as defined in claim 9, wherein said step (c) comprises the step of scanning said workpiece and said platen in perpendicular and parallel directions by two separate scan mechanisms.

14. A method as defined in claim 13, wherein one of said scan mechanisms is configured to scan said workpiece and said platen in said direction parallel to said ion beam relative to a fixed element.

15. A method as defined in claim 13, wherein one of said scan mechanisms is configured to scan said workpiece and said platen in said direction parallel to said ion beam relative to a movable element for the other of said scan mechanisms.

16. A method as defined in claim 9, wherein said step (c) comprises the step of scanning said workpiece and said platen in perpendicular and parallel directions by one mechanism.

17. A method for ion implantation, comprising the steps of:
(a) generating an ion beam;
(b) tilting a workpiece at a tilt angle with respect to said ion beam; and
(c) scanning the workpiece in a direction parallel to a surface of said workpiece.

18. A method as defined in claim 17, wherein said workpiece is a semiconductor wafer.

19. A method as defined in claim 17, wherein said ion beam is a beam substantially having a cylindrical shape.

20. A method as defined in claim 17, wherein said ion beam is a ribbon beam.
